(19) United States
(12) Patent Application Publication
(10) Pub. No.: US 2012/0025174 A1
(43) Pub. Date: Feb. 2, 2012

(54) PASSIVATING LAYER FOR FLEXIBLE ELECTRONIC DEVICES

(76) Inventors: Kwanghee LEE, Gwangju (KR); Alan J. HEEGER, Santa Barbara, CA (US)

(21) Appl. No.: 12/986,082

(22) Filed: Jan. 6, 2011

Related U.S. Application Data
(63) Continuation of application No. 11/650,574, filed on Jan. 4, 2007, now abandoned.
(60) Provisional application No. 60/756,604, filed on Jan. 4, 2006.
(60) Provisional application No. 60/872,401, filed on Feb. 1, 2006.

(51) Int. Cl. H01L 51/30

(52) U.S. Cl. 257/40; 257/E51.027; 257/288

(57) ABSTRACT

An electronic device which comprises a first electrode, a second electrode, an active polymer layer between the first and the second electrodes, and a passivating layer adapted to enhance the lifetime of the electronic device. The passivating layer comprises a substantially amorphous titanium oxide having the formula of TiOₓ where x represents a number from 1 to 1.96.

### CROSS-REFERENCE TO RELATED APPLICATIONS

This application claims the benefit of priority under 35 U.S.C. §119(e) to U.S. Provisional Application Ser. No. 60/756,604 filed Jan. 4, 2006 and No. 60/872,401 filed Feb. 1, 2006, the disclosures of which are incorporated herein by reference in their entirety.

### BACKGROUND

This invention relates generally to polymer-based electronic devices and in particular to electronic devices comprising titanium oxides with improved device efficiency, performance and lifetime.

Electronic devices based on semiconducting and metallic polymers provide special opportunities for novel products as they can be fabricated in large areas using low cost printing and coating technologies to deposit and simultaneously pattern active electronic materials on lightweight flexible substrates. Products based on printed plastic electronics are expected to develop into a significant industry with a more than $100 billion market opportunity that is enabled by a new generation of low-cost, lightweight, and flexible electronic devices.

Although electronic devices such as diodes, field effect transistors (FETs), light-emitting diodes (LEDs), solar cells, and photodetectors fabricated from semiconducting and metallic polymers have been demonstrated with performance comparable to or in some cases even better than their inorganic counterparts, the typically short lifetime of the polymer-based devices must be overcome before large scale commercialization can be realized. Most conventional semiconducting polymer materials are degraded when exposed to water vapor and/or oxygen in the air. Photo-oxidation is often a serious problem to polymer-based electronic devices.

The degradation of polymer devices can be eliminated or at least reduced to acceptable levels by sealing the components inside an impermeable package using glass and/or metal (sometimes with a desiccant inside) to prevent exposure to oxygen and water vapor. Attempts to create flexible packaging using hybrid multilayer barriers comprised of inorganic oxide layers separated by polymer layers with total thickness of 5-7 μm have been reported with promising results. Although such encapsulation methods can reduce oxygen and moisture permeation, they are expensive and typically result in increased thickness and loss of flexibility. To achieve the goal of simple fabrication by solution processing—flexibility and thin film factor for printed plastic electronics—improved barrier materials for packaging and/or devices with reduced sensitivity are needed to enable large scale commercialization on plastic substrates.

Photocatalysis by titania (TiO₂) has been extensively investigated, especially for air and water purifications. These applications are based on photogeneration of electron-hole pairs by absorption of photons with energies greater than the band gap (in the ultraviolet) of nanoparticulate TiO₂ suspensions or films. These relatively high energy electron-hole pairs can react at the TiO₂ surface to drive photocatalytic or photosynthetic redox reactions. If appropriate electron acceptors (e.g., oxygen) and electron donors (e.g., organic molecules) are adsorbed onto a semiconductor surface, interfacial electron-transfer reactions take place, resulting, in for example, complete photo-mineralization of the organic to carbon dioxide, water, and mineral acids. During the process, oxygen consumption is a principal factor in the photocatalytic reaction. In addition, because Ti is sufficiently reactive the oxygen-deficient surfaces are expected to react with O₂. Studies have shown that TiO₂ has a substantial oxygen scavenging effect originating from the combination of the photocatalysis process and oxygen deficiencies within the structure. As a consequence, TiO₂ has been developed as an active packaging material for oxygen-sensitive products such as pharmaceuticals, medical instruments, museum pieces, and oxygen-sensitive foods.

For many reasons water is also an important adsorbate on TiO₂ surfaces. Many applications and in fact most photocatalytic processes are performed in the presence of water vapor. Ambient water vapor interacts with TiO₂ surfaces, and the resulting surface hydroxyl group can affect the adsorption and reaction processes. The adsorption of water on TiO₂ has been of intense interest in recent years.

The various aspects of the photocatalytic activity of TiO₂ are reviewed extensively in the art. The main features of the process can be briefly summarized as follows. The primary excitation results in an electron in the conduction band and a hole in the valence band. When TiO₂ is in contact with an electrolyte, the Fermi level equilibrates with the redox potential of the redox couple. The resulting Schottky barrier drives the electron and the hole in different directions. The components of the electron-hole pair, when transferred across the interface, are capable of reducing and oxidizing an adsorbate, forming a singly oxidized electron donor and a singly reduced electron acceptor, as shown in detail in the following equations:

TiO₂+hv→TiO₂ (e⁻, h⁺) (1)

TiO₂(h⁺)+RX_{ads}→TiO₂RX_{ads}^{•+} (2)

TiO₂(h⁺)+H₂O_{ads}→TiO₂+OH_{ads}^{•}+H⁺ (3)

TiO₂(h⁺)+OH_{ads}^{-→TiO}₂+OH_{ads}^{•} (4)

TiO₂(e⁻)+O_{2,ads}→TiO₂^{•-} (5)

TiO₂(e⁻)+H₂O_{2,ads}→TiO₂+OH⁻+OH_{ads}^{•} (6)

These processes generate anion or cation radicals which can undergo subsequent reactions. Hydroxyl radicals are generally considered the most important species in the photocatalytic degradation of organics, although not in UHV-based studies. It is generally believed that hole capture is directly through OH and not via water first, i.e. through Eq. (4) rather than Eq. (3). The 1b₁ orbital of water lies above the 1π level of OH, so one might expect water to be better at capturing a hole than OH, but the radical-cation of water may be neutralized before decomposing into an OH radical. Also, it is mostly assumed that the surface is OH covered and therefore the hole is directly transferred to OH.

The photocatalytic activity of TiO₂ is completely suppressed in the absence of an electron scavenger such as molecular oxygen. Because the conduction band of TiO₂ is almost isoenergetic with the reduction potential of oxygen in inert solvents, adsorbed oxygen serves as an efficient trap for photogenerated electrons. The resulting species, superoxide, O₂^{•-}, is highly reactive and can attack other adsorbed molecules. Several other oxidation processes, in addition to reactions shown in Eq.(1)-(6) can occur as well. Often, loading of TiO₂ with Pt and addition of H₂O₂ [Eq.(6)] enhance the overall efficiency of the photocatalytic degradation processes.

In order for photocatalysis to be efficient, electron-hole pair recombination must be suppressed before the trapping reactions occur at the interface. The recombination reaction occurs very fast, and the resulting low quantum efficiency is one of the main impediments for the use of TiO₂. Degradation of airborne pollutants has resulted in an explosion of TiO₂-permeated paints and papers to clean up everything from cigarette smoke to acetaldehyde.

TiO₂ has substantial oxygen/water scavenging effects originating from the combination of photocatalysis and inherent oxygen deficiency of the TiO₂ structure. Since oxygen and water vapor are principally responsible for degradation of polymer devices, incorporation of TiO₂ into or onto polymer devices seems to be an ideal solution for reducing the sensitivity of such devices to oxygen and water vapor.

However, since crystalline TiO₂ layers (anatase or rutile phase) can only be prepared at temperatures above 450° C., the formation of a protective TiO₂ layer in/on the device structure is not consistent with the fabrication of polymer electronic devices. Active organic layers cannot survive such high temperatures.

The following documents include information generally related to this invention and are incorporated herein by reference in their entirety.

1. G. P. Collins, Scientific American, August 2004, p. 76, 2004; W. E. Howard, Scientific American, February 2004, p. 76 (2004).

2. H. Tomozawa, D. Braun, S. Pillips, A. J. Heeger, and H. Kroemer, Synth. Met. 22, p. 63, (1987).

3. H. Sirringhaus, N. Tessler, and R. H. Friend, Science 280, p 1741 (1998).

4. J. H. Burroughes, D. D. C. Bradley, A. R. Brawn, R. N. Marks, R. H. Friend, P. L. Burns, and A. B. Holmes, Nature 335, p. 539 (1990).

5. G. Yu, J. Gao, J. C. Hummelen, F. Wudl, and A. J. Heeger, Science 270, p. 1789 (1995).

6. G. Yu and A. J. Heeger, J. Appl. Phys. 78, p. 4510 (1995).

7. R. D. Scurlock, B. Wang, P. R. Ogilby, J. R. Sheats, and R. L. Clough, J. Am. Chem. Soc. 117, p. 10194 (1995)

8. K. Z. Xing, N. Johansson, G. Beamson, D. T. Clark, J-L. Bredas, and W. R. Salaneck, Adv. Mater. 9, p. 1027 (1997).

9. P. E. Burrows, V. Bulimic, S. R. Forrest. L. S. Capuche, D. M. McCarty, and M. E. Thompson, Appl. Phys. Let. 65, p. 2922 (1994).

10. M. S. Weaver, L. A. Michaels, K. Raja, M. A. Rothman, J. A. Silver nail, J. J. Brown, P. E. Burrows, G. L. Graff, M. E. Gross, P. M. Martin, M. Hall, E. Mast, C. Bonham, W. Bennett, and M. Turnoff, Appl. Phys. Let. 81, p. 2929 (2002).

11. B. Chwang, M. A. Rothman, S. Y. Mao, R. H. Hewitt, M. S. Weaver, J. A. Silvernail, K. Rajan, M. Hack, J. J. Brown, X. Chu, L. Moro, T. Krajewski, N. Rutherford, Appl. Phys. Lett. 83, p. 413 (2003).

12. Fujishima and K. Honda, Nature 238, p. 37 (1972).

13. R. Wang, K. Hashimoto, A. Fujishima, M. Chikuni, E. Kojima, A. Kitamura, M. Shimohigoshi, and T. Watanabe, Nature 388, p. 431 (1997).

14. U. Diebold, Surface Science Reports 48, p. 53 (2003).

15. Mills, H. R. Davies, and D. Worsley, Chem. Soc. Rev. 22, p. 417 (1993).

16. O. Legrini, E. Oliveros and A. M. Braun, Chem. Rev. 93, p. 671 (1993).

17. Heller, Acc. Chem. Res. 28, p. 503 (1995)

18. M. Hoffman, S. Martin, W. Choi, and D. Bahnemann, Chem. Rev. 95, p. 69 (1995).

19. L. Linsebigler, G. Lu, and J. T. Yates Jr., Chem. Rev. 95, p. 735 (1995).

20. V. E. Henrich and P. A. Cox, The Surface Science of Metal Oxides, Cambridge University Press, Cambridge (1994).

21. Noguera, Physics and Chemistry of Oxide Surfaces, Cambridge University Press, Cambridge (1996).

22. G. Lu, A. Linsebigler, and J. T. Yates Jr., J. Chem. Physa 102, p. 4657 (1995).

23. N. Rusu and J. T. Yates Jr., Langmuir 13, p. 4311 (1997).

24. L. Xio-e, A. N. M. Green, S. A. Hague, A. Mills, J. R. Durrant, J. Photochem. Photobiol. A 162, p. 253 (2004).

25. M. Peiro, G. Doyle, A. Mills, and J. R. Durrant, Adv. Mater. 17, p. 2365 (2005).

26. Thiel and T. E. Madley, Surf. Sci. Rep. 7, p. 211 (1987).

27. M. A. Henderson, Surf. Sci. Rep. 46, p. 1 (2002).

28. U. Diebold, Surface Science Reports 48, p. 53 (2003).

29. O. Legrini, E. Oliveros, and A. M. Braun, Chem. Rev. 93, p. 671 (1993).

30. Heller, Acc. Chem. Res. 28, p. 503 (1995).

31. L. Perkins and M. A. Henderson, J. Phys. Chem. B 105, p. 3856 (2001).

32. U. Diebold, Surface Science Reports 48, p. 53 (2003).

33. Wilson, Chemical &Engineering News 1, p. 29 (1996).

34. U. Diebold, Surface Science Reports 48, p. 53 (2003).

35. L. Xio-e, A. N. M. Green, S. A. Hague, A. Mills, J. R. Durrant, J. Photochem. Photobiol. A 162, p. 253 (2004).

36. M. Peiro, G. Doyle, A. Mills, and J. R. Durrant, Adv. Mater. 17, p. 2365 (2005).

37. T. A. Skotheim, R. L. Elsenbaumer, and J. R. Reynolds, Handbook of Conducting Polymers 2^{nd} ed., Eds, Dekker, New York (1998).

38. G. Hadziioannou and P. F. van Hutten, Semiconducting Polymers, Eds, Wiley-VCH, Weinheim (2000).

39. J. Campbell, D. D. C. Bradley, and D. G. Lidzey, J. Appl. Phys. 82, p. 6326 (1997).

40. H.-F. Meng and Y.-S. Chen, Phys. Rev. B 70, p. 115208 (2004).

41. D. Parker, J. Appl. Phys. 75, p. 1656 (1994).

42. O'Brien, M. S. Weaver, D. G. Lidzey, and D. C. Bradley, Appl. Phys. Lett. 69, p. 881 (1996).

43. L. S. Hung, C. W. Tang, and M. G. Mason, Appl. Phys. Lett. 70, p. 152 (1997).

44. W. Ma, P. K. Iyer, X. Gong, B. Liu, D. Moses, G. C. Bazan, and A. J. Heeger, Adv. Mater. 17, p. 274 (2005).

45. H. Becker, S. E. Burns, and R. H. Friend, Phys. Rev. B 56, p. 1893 (1997).

46. S. H. Kim, J. Y. Kim, S. H. Park, and K. Lee, Proc. SPIE Vol. 5937, p. 59371G1 (2005).

47. L. A. Pettersson, L. S. Roman, and 0. Inganäs, J. Appl. Phys. 86, p. 487 (1999).

48. T. Stübinger and W. Brütting, J. Appl. Phys. 90, p. 3632 (2001).

49. H. Hansel, H. Zettl, G. Krausch, R. Kisselev, M. Thelakkat, and H.-W. Schmidt, Adv. Mater. 15, p. 2056 (2003).

50. H. J. Snaith, N. C. Greenham, and R. H. Friend, Adv. Mater. 16, p. 1640 (2004).

51. Melzer, E. J. Koop, V. D. Mihaletchi, and P. W. M. Blom, Adv. Funct. Mater. 14, p. 865 (2004).

52. O'Regan and M. Gräzel, Nature 353, p. 737 (1991).

53. U. Bach, D. Lupo, P. Comte, J. E. Moser, F. Weissortel, J. Salbeck, H. Spreitzer, and M. Grätzel, Nature 395, p. 583 (1998).

54. C. Arango, L. R. Johnson, V. N. Bliznyuk, Z. Schlesinger, S. A. Carter, and H.-H. Horhold, Adv. Mater. 12, p. 1689 (2000).

55. J. Breeze, Z. Schlesinger, S. A. Carter, and P. J. Brock, Phys. Rev. B 64, p. 125205 (2001).

56. M. Thelakkat, C. Schmitz, and H.-W. Schmidt, Adv. Mater. 14, p. 577 (2002).

57. Wang, J. Swensen, D. Moses, A. J. Heeger, J. Appl. Phys. 93, p. 6137 (2003).

58. T. Sugimooto, et al., J. Colloid Interface Sci. 259, 43-52 (2003).

59. W. Shangguan, et al., Sol. Energy Mater. Sol. Cells 80, 433-441 (2003).

60. S. Lee, et al., Chem. Mater. 16, 4292-4295 (2004).

61. Z. Zhong, et al., Chem. Mater. 17, 6814-6818 (2005).

62. U. Scherf and E. J. W. List, Adv. Mater. 14, p. 477 (2002).

63. Spreitzer, H. Becker, E. Kluge, W. Kreuder, H. Schenk, R. Demandt, and H. Schoo, Adv. Mater. 10, p. 1340 (1998).

64. S. H. Kim, J. Y. Kim, S. H. Park, and K. Lee, Proc. SPIE Vol. 5937, p. 59371G1 (2005)

65. S. H. Kim, J. Y. Kim, S. H. Park, and K. Lee, Appl. Phys. Lett., (2005).

66. J. H. Park, O. 0. Park, J.-W. Yu, J. K. Kim, and Y. C. Kim, Appl. Phys. Lett. 84, p. 1783 (2004).

67. S. H. Kim, J. Y. Kim, S. H. Park, and K. Lee, Proc. SPIE Vol. 5937, p. 59371G1, (2005).

68. S. H. Kim, J. Y. Kim, S. H. Park, and K. Lee, Appl. Phys. Lett., (2005).

69. T. D. Anthopoulos, D. M. de Leeuw, E. Cantatore, S. Setayesh, E. J. Meijer, C. Tanase, J. C. Hummelen, and P. W. M. Blom, Appl. Phys. Lett. 85, p. 4205 (2004).

70. T. D. Anthopoulos, C. Tanase, S. Setayesh, E. J. Meijer, J. C. Hummelen, P. W. M. Blom, and D. M. de Leeuw, Adv. Mater. 16, p. 2174 (2004).

71. Tapponnier, I. Biaggio, and P. Gruner, Appl. Phys. Lett. 86, p. 112114 (2005).

### SUMMARY OF THE INVENTION

An electronic device is provided comprising a first electrode, a second electrode, an active polymer layer between the first and the second electrodes, and a passivating layer adapted to enhance lifetime of the electronic device. The passivating layer comprises a substantially amorphous titanium oxide having the formula of TiOₓ where x represents a number from 1 to 1.96.

In some embodiments, a light-emitting diode is provided comprising an electron-injecting electrode, a hole-injecting electrode, a luminescent polymer layer between the electron-injecting electrode and the hole-injecting electrode, and a layer of substantially amorphous titanium oxide having the formula of TiOₓ where x represents a number from 1 to 1.96.

In some embodiments, a field-effect transistor is provided comprising a gate electrode, a gate dielectric, a source electrode, a drain electrode, a semiconducting polymer layer, and a layer of substantially amorphous titanium oxide having the formula of TiOₓ where x represents a number from 1 to 1.96.

In some embodiments, a photodetector is provided comprising an electron-collecting electrode, a hole-collecting electrode, a photoactive, charge-separating layer comprising a semiconducting polymer blended with a suitable acceptor between the electron-collecting and the hole-collecting electrode, and a layer of substantially amorphous titanium oxide having the formula of TiOₓ where x represents a number from 1 to 1.96.

In another aspect, a method of preparing an electronic device having a polymer-based active layer is provided comprising the step of applying a solution of a titanium oxide precursor to form a layer of substantially amorphous titanium oxide having the formula of TiOₓ where x represents a number from 1 to 1.96.

### BRIEF DESCRIPTION OF THE DRAWINGS

These and various other features and advantages of the present invention will become better understood upon reading of the following detailed description in conjunction with the accompanying drawings and the appended claims provided below, where:

FIG. 1 is a schematic illustrating a polymer light-emitting diode (PLED) structure comprising a TiOₓ layer in accordance with one embodiment of the invention;

FIG. 2 is a schematic illustrating a polymer solar cell comprising a TiOₓ layer in accordance with one embodiment of the invention;

FIG. 3 is a schematic illustrating a n-type field-effect transistor (FET) structure comprising a TiOₓ layer in accordance with one embodiment of the invention;

FIG. 4 is a diagram illustrating energy levels for a device having an ITO/PEDOT:PSS/MEH-PPV/TiOₓ/Al structure in accordance with one embodiment of the invention;

FIG. 5A is an atomic force microscope (AFM) scan of the surface of a TiOₓ layer in accordance with one embodiment of the invention;

FIG. 5B is an X-ray diffraction pattern of a TiOₓ layer and its crystalline form after conversion at 500° C. in accordance with one embodiment of the invention;

FIG. 5C is a graph showing an absorption spectrum of a TiOₓ film in accordance with one embodiment of the invention. The spectrum shows that the TiOₓ film is substantially transparent in the visible range;

FIG. 6A is photoluminescence (PL) spectra of polyfluorene (PF) films with and without a TiOₓ layer before annealing in accordance with one embodiment of the invention;

FIG. 6B is PL spectra of PF films with and without a TiOₓ layer after annealing for 15 hours at 150° C. in the air in accordance with one embodiment of the invention;

FIG. 7 is an X-ray photoelectron spectroscopy (XPS) of O₁ₛ in the polymer in structures of glass/polymer and glass/polymer/TiOₓ in accordance with one embodiment of the invention;

FIG. 8A is a graph showing current density-voltage (J-V) characteristics for polymer light-emitting devices comprising MEH-PPV polymer with and without a TiOₓ layer in accordance with one embodiment of the invention;

FIG. 8B is a graph showing brightness-voltage (L-V) characteristics for polymer light-emitting devices comprising MEH-PPV polymer with and without a TiOₓ layer in accordance with one embodiment of the invention;

FIG. 9 is a graph comparing the luminous efficiency of PLEDs with and without a TiOₓ layer in accordance with one embodiment of the invention;

FIG. 10 is a schematic illustrating the charge injection for PLEDs with and without an electron injection/transport layer in accordance with one embodiment of the invention;

FIG. 11A is a graph illustrating device characteristics of PLEDs that do not include a TiOₓ layer;

FIG. 11B is a graph illustrating device characteristics of PLEDs that include a TiOₓ layer in accordance with one embodiment of the invention;

FIG. 12 is a graph comparing the brightness and luminous efficiency as a function of storage time for PLEDs with and without a TiOₓ layer in accordance with one embodiment of the invention;

FIG. 13A is a graph showing current density-voltage (J-V) characteristics of polymer solar cells that do not include a TiOₓ layer;

FIG. 13B is a graph showing current density-voltage (J-V) characteristics of polymer solar cells that include a TiOₓ layer in accordance with one embodiment of the invention;

FIG. 14 is a graph comparing the power conversion efficiency as a function of time for polymer solar cells with and without a TiOₓ layer in accordance with one embodiment of the invention;

FIG. 15 is a graph comparing transfer characteristics of PCBM FETs with and without a TiOₓ capping layer in accordance with one embodiment of the invention; the typical n-type I_{ds} versus V_{ds} characteristics of a PCBM-FET with a TiOₓ capping layer are shown in an inset in FIG. 15;

FIG. 16A is a graph showing changes of transfer characteristics of PCBM FETs that do not include a TiOₓ capping layer in accordance with one embodiment of the invention;

FIG. 16B is a graph showing changes of transfer characteristics of PCBM FETs that include a TiOₓ capping layer;

FIG. 17 is a graph showing the field-effect mobility of PCBM FETs with and without a TiOₓ capping layer versus exposure time to the air in accordance with one embodiment of the invention;

FIG. 18 is a graph showing the field-effect mobility of P3HT FETs with and without a TiOₓ capping layer versus exposure time to the air in accordance with one embodiment of the invention;

FIG. 19A is a schematic illustrating the spatial distribution of the squared optical electric field strength |E|² inside the devices having a structure of ITO/PEDOT/Active-Layer/Al (left) and a structure of ITO/PEDOT/Active-Layer/Optical Spacer/Al (right);

FIG. 19B is a schematic illustrating a device structure with a brief flow chart of the steps involved in preparation of a TiOₓ layer in accordance with one embodiment of the invention;

FIG. 19C is a schematic showing the energy level of the single components of the photovoltaic cell shown in FIG. 19B;

FIG. 20 A is a graph showing incident monochromatic photon to current collection efficiency (IPCE) spectra for devices with and without a TiOₓ optical spacer layer;

FIG. 20B is a graph showing the change in absorption spectrum resulting from addition of an optical spacer. The lower dashed line represents the absorption of P3HT:PCBM obtained from transmittance measurements. The inset is a schematic description of the optical beam path in the samples;

FIG. 21A is a graph showing current density-voltage (J-V) characteristics of polymer solar cells with and without a TiOₓ optical spacer illuminated with 25 mW/cm²at 532 nm;

FIG. 21B is a graph showing current density-voltage (J-V) characteristics of polymer solar cells with and without a TiOₓ optical spacer under AM1.5 illumination from a calibrated solar simulator with an intensity of 90 mW/cm²; and

FIG. 22 is a schematic illustrating the mechanism for enhancing lifetime of the devices comprising a TiOₓ layer in accordance with one embodiment of the invention.

### DETAILED DESCRIPTION OF VARIOUS EMBODIMENTS

Various embodiments of the invention are described hereinafter with reference to the figures. It should be noted that some figures are schematic and the figures are only intended to facilitate the description of specific embodiments of the invention. They are not intended as an exhaustive description of the invention or as a limitation on the scope of the invention. In addition, one aspect described in conjunction with a particular embodiment of the present invention is not necessarily limited to that embodiment and can be practiced in any other embodiments of the present invention. For instance, various embodiments are provided in the drawings and the description in connection with polymer light-emitting diodes, photovoltaic cells, and field-effect transistors. It will be appreciated that the claimed invention may also be used in other electronic devices.

In general, the invention provides a structure useful in various electronic devices. The structure comprises a polymer layer having a first surface and a second surface, and a substantially amorphous TiOₓ layer on the first surface, where in the formula of TiOₓ, x represents a number from 1 to 1.96, preferably from 1.1 to 1.9, and more preferably from 1.2 to 1.9. These values represent from 50% to 98% full oxidation, preferably 55% to 95%, and more preferably 60% to 95% full oxidation.

In some embodiments, the invention provides a structure comprising a polymer layer having two opposing sides and a substantially amorphous TiOₓ layer on each of the opposing sides, wherein in the formula of TiOₓ, x represents a number from 1 to 1.96, preferably from 1.1 to 1.9, and more preferably from 1.2 to 1.9.

The polymer layer in the structures of the invention can be formed of various polymers that are active or functional in various electronic devices. Active polymers suitable for the invention include conducting or semiconducting polymers, and luminescent polymers, known more generally as conjugated polymers with molecule structures well known in the art. Various exemplary polymers are provided below in connection with specific applications.

The thickness of the amorphous TiOₓ layer can range from 5 to 500 nm, depending on specific applications. In most applications, the thickness can range from 5 to 100 nm. In some applications, good results can be obtained with the thickness ranging from 10 to 50 nm, or from 10 to 40 nm.

In some embodiments, the invention provides an electronic device comprising a first electrode, a second electrode, an active polymer layer positioned between the first and the second electrode, and a substantially amorphous TiOₓ layer between the active polymer layer and the second electrode, wherein in the formula of TiOₓ, x represents a number from 1 to 1.96, preferably from 1.1 to 1.9, and more preferably from 1.2 to 1.9. Exemplary electronic devices include but are not limited to diodes, light-emitting diodes, photodiodes, field-effect transistors, photodetectors, and photovoltaic cells etc.

Solution-Processed Titanium Oxide (TiOₓ) Layer in Polymer Diodes, Photodiodes and Light-Emitting Diodes

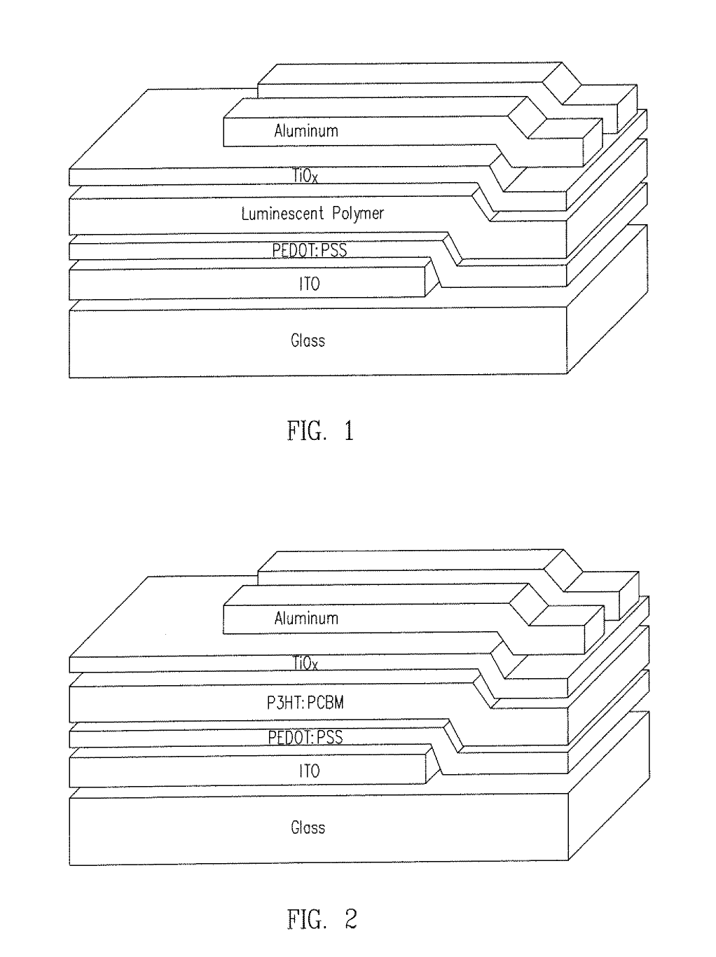

FIG. 1 schematically shows a light-emitting diode (LED) structure comprising a TiO_{X} layer in accordance with one embodiment of the invention. As shown, the LED is a thin-film device fabricated in a metal-insulator-metal configuration. The LED comprises a substrate such as glass, a high work function electrode such as transparent indium-tin oxide and a hole injection layer such as, for example, poly(3,4-ethylenedioxylenethiophene)-polystyrene sulfonic acid (ITO/PEDOT:PSS) bilayer electrode deposited on the substrate, a low work function electrode such as metal aluminum of thickness around 100 nm, and a luminescent polymer layer sandwiched between the two electrodes. The high work function electrode injects hole carriers. The low work function electrode injects electron carriers. The low mobility of the charge carriers in polymers (μ˜10⁻¹-10⁻⁶ cm²/Vs) typically requires that the thickness of the active layer be less than a few hundred nanometers.

A layer of TiOₓ is formed on the luminescent polymer layer. As described in more detail below, a TiOₓ layer can be formed by a solution-based sol-gel process, which is desirable for fabrication of the active polymer layer. The thickness of the TiOₓ layer can range from 5 to 500 nm. In one embodiment, a TiOₓ layer having a thickness of about 20 nm provides good device performance and lifetime for the LED. In the formula of TiOₓ, x represents a number less than 2 such that the material is a “suboxide.” In general, x in the formula of TiOₓ is a number from 1 to 1.96, preferably from 1.1 to 1.9, and more preferably from 1.2 to 1.9. These values represent from 50% to 98% full oxidation, preferably 55% to 95%, and more preferably 60% to 95% full oxidation.

By introducing a TiOₓ layer between a luminescent polymer layer and a metal electrode, the LED performance is significantly enhanced. The enhanced performance can be contributed to the specific properties of the new TiOₓ materials summarized as follows:

Energy levels of the bottom of the conduction band (LUMO) and the top of the valence band (HOMO) well-matched with the electronic structure requirements (electron accepting and electron transporting, but hole blocking);

Relatively high electron mobility (μₑ≈1.7×10⁻⁴ cm²/Vs) as determined by time-of-flight measurements;

Sol-gel process compatible with solution processing of polymer electronics;

Transparency in the visible range with an energy band gap around 3.7 eV; and

TiOₓ layer formation on top of an active polymer without disturbing the polymer layer(s) below.

To achieve efficient electroluminescence (EL), a balanced bipolar injection and transport of carriers is needed. Improved electron injection can be achieved by choosing a low work function metal as the cathode material. Higher efficiencies can be achieved by confining electrons and holes within the emitting layer by using multilayer device structures with hole transport (electron blocking) layer on the cathode side and an electron transport (hole blocking) layer on the anode side. The TiOₓ layer inserted between the cathode and the emitting layer according to embodiments of the invention can effectively function as an electron transport and a hole blocking layer, and as a result, enhance the device performance.

There are other beneficial effects by inserting a TiOₓ layer according to embodiments of the invention: preventing diffusion of metal ions from the cathode into the luminescent polymer layer and quenching of luminescence by proximity to the metal cathode. Diffusion of metal ions into the polymer layer may reduce the lifetime of the device. Because of diffusion, alkali metals are typically not used as cathode materials as the devices may quickly short out, although this problem is less severe for divalent alkaline earth metals. The device lifetime is significantly longer with Ba as the cathode material than with Ca (the higher mass of Ba inhibits diffusion). The diffusion problem can be eliminated or significantly reduced by inserting a TiOₓ layer according to embodiments of the invention.

When the average distance between the cathode and the emitting oscillators within the luminescent polymer is too small, the losses from the metallic electrode quench the luminescence. This quenching effect is particularly harmful in devices in which the electron mobility is smaller than the hole mobility (typically the case in semiconducting polymers) since the recombination zone is closer to the cathode interface. This quenching problem can be largely eliminated by inserting a TiOₓ layer between the luminescent polymer and the metal cathode.

The lifetime of the light-emitting diodes can be extended by inserting a TiOₓ layer between the polymer emitting layer and the metal cathode. This benefit will be demonstrated in more detail in the Examples provided below.

The TiOₓ films according to embodiments of the invention can be prepared using a sol-gel processed TiOₓ precursor solution as will be described in more detail below. Atomic force microscope (AFM) scans show that the resulting TiOₓ films are smooth with surface features smaller than a few nanometers and is substantially amorphous. The TiOₓ forms a high quality film on top of the active polymer layer.

The energy levels of the bottom of the conduction band (LUMO) and the top of the valence band(HOMO) of the TiOₓ material obtained from optical absorption and Cyclic Voltammetry (CV) data are shown in FIG. 4. The HOMO and LUMO energy levels for the other materials in FIG. 4 are known in the art. The energy level diagram shown in FIG. 4 demonstrates that the TiOₓ layer satisfies the electronic structure requirements of an electron transport layer: the conduction band edge of TiOₓ is 4.4 eV, which is well matched with the energy level of Al cathode (4.3 eV). Because of the large band gap of TiOₓ, holes are blocked at the polymer-TiOₓ interface.

Solution-Processed Titanium Oxide (TiOₓ) as an Optical Spacer and Electron Transport Layer in Polymer Solar Cells and Photodetectors

FIG. 2 schematically shows a polymer-based photovoltaic cell or photodetector comprising a TiOₓ layer in accordance with one embodiment of the invention (a photovoltaic cell operates in reverse bias functions as to a photodetector). The photovoltaic cell or photodetector is a thin film device and fabricated in a metal-insulator-metal configuration. As shown, the device comprises a substrate such as glass, a transparent high work electrode formed on the substrate for collecting hole carries such as a bilayer electrode comprising a hole injection layer such as, for example, poly(3,4-ethylenedioxylenethiophene)-polystyrene sulfonic acid (PEDOT:PSS) and indium-tin-oxide (ITO), a low work function metal electrode such as aluminum (or Calcium or Barium, for example) for collecting electron carriers, and an absorbing and charge separating bulk heterojunction layer with a thickness of approximately 100 nm sandwiched between the two charge selective electrodes. Other materials such as conducting oxides, metallic polymers and the like well known in the art can also be used for the transparent electrode. The work function difference between the two electrodes provides a built-in potential that breaks the symmetry, thereby providing a driving force for the photo-generated electrons and holes toward their respective electrodes. By way of example, the bulk heterojunction layer can be poly(3-hexylthiophene) and [6,6,]-phenyl-C₆₁-butyric acid methyl ester (P3HT:PCBM).

A titanium oxide (TiOₓ) layer can be deposited on top of the active polymer layer using a solution-based sol-gel process as will be described in more detail below. In the formula of TiOₓ, x represents a number of less than 2 such that the material is a “suboxide.” Usually, x is a number from 1 to 1.96, preferably from 1.1 to 1.90, and more preferably from 1.2 to 1.90. The TiOₓ layer significantly improves the power conversion efficiencies and device lifetime.

Introducing a TiOₓ layer as an optical spacer between an active layer and a metal electrode in a photovoltaic cell changes the spatial redistribution of light intensity inside the device. TiOₓ is an ideal material for an optical spacer because it is a good acceptor and an electron transport material with a conduction band edge lower in energy than that of the lowest unoccupied molecular orbital (LUMO) of C₆₀, and the LUMO is close to the Fermi energy of the collecting metal electrode. TiOₓ is transparent to light with wavelengths within the solar spectrum.

A TiOₓ layer improves the performance of polymer photovoltaic cells. The power conversion efficiencies of the devices can be increased by approximately 50% compared to similar devices fabricated without a TiOₓ optical spacer. A TiOₓ layer also improves the lifetime of polymer photovoltaic cells as shown in the following Examples.

Solution-Processed Titanium Oxide (TiOₓ) as a Capping Layer in Polymer Field Effect Transistors and Other Plastic Electronic Devices

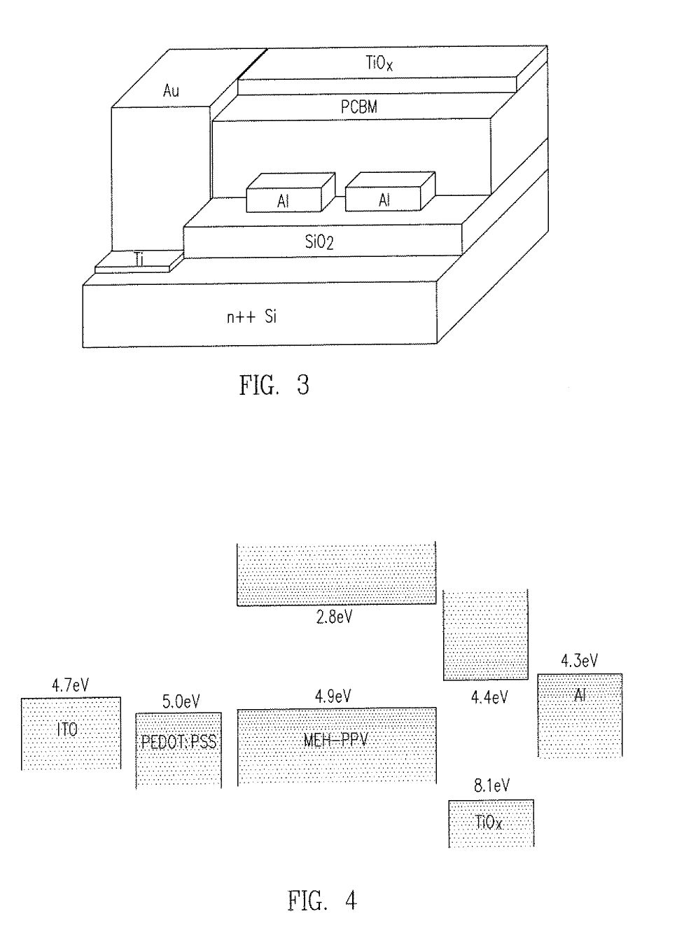

FIG. 3 schematically shows a field-effect transistor (FET) structure comprising a TiOₓ layer in accordance with one embodiment of the invention. As shown, the FET structure comprises a substrate such as a heavily doped n-type Si wafer. The doped n-type Si wafer functions as a gate electrode. Other substrates such as for example glass, flexible plastic substrates or free standing metal foils coated with an insulating layer can also be used. A SiO₂ layer (gate dielectric) with a thickness of such as 200 nm is thermally grown on the substrate. The gate dielectric layer can also be made from a wide variety of other insulators. The source and drain electrodes (e.g. Al, Au, Ag, etc.) can be deposited on the dielectric layer by methods well known in the art such as by e-beam evaporation or metal vapor deposition after patterning using shadow masks or standard photolithographic methods. A semiconducting polymer layer such as P3HT or an organic semiconducting layer such as PCBM is deposited on the gate dielectric layer and covers the source and drain electrodes. The FET channel is defined by the source and drain electrodes. A TiOₓ layer is formed on the semiconducting polymer layer using solution processing method as will be described in more detail below. It should be noted that FIG. 3 shows a bottom contact configuration in which metal source and drain electrodes are deposited on the dielectric layer. Alternatively, the source and drain electrodes can be deposited on the top of the semiconducting polymer layer. In either case, the field induced carriers are confined within the semiconducting layer to a thickness of a few nanometers near the interface with the gate dielectric.

As will be demonstrated in more detail in the following Examples, a FET comprising a TiOₓ layer significantly improves the device performance and lifetime. While the invention is not limited to any theories, it is believed that a TiOₓ layer acts as a barrier layer and a scavenging layer that prevents the diffusion of oxygen and humidity into the active polymer layer, thereby increasing the device lifetime by factors approaching two orders of magnitude. Moreover, the solution-based low temperature process for depositing a TiOₓ layer is compatible with the device architectures for FETs fabricated from semiconducting polymers. The TiOₓ layer reduces the sensitivity to oxygen and water vapor to a point where simple barrier materials might be sufficient to enable the lifetime required for printed, flexible, plastic electronics.

It should be pointed out that TiOₓ layers can be positioned between the active organic layer and one or both of the electrodes. In addition, the advantages of a TiOₓ layer can be realized when it is applied as an overlayer or outer boundary layer in polymer-based electronic devices. Thus, one can advantageously employ one, two or even three TiOₓ layers in these devices.

Solution Processing

The TiOₓ layer according to embodiments of the invention can be incorporated into multilayer microelectronic or micro optoelectronic devices. Such devices may include one or more organic polymer layers. These organic polymer layers can provide a substrate for the devices or in many embodiments, are present as conducting, semiconducting, or other functional active layers. The processing conditions for applying TiOₓ layers need to be compatible with the polymer layers which are more sensitive to high temperatures than the metal layers, inorganic semiconducting layers, silicon layers and glass layers that are often found in microelectronic devices. In addition, organic polymer layers are more sensitive to certain types of solvents than many of the inorganic materials described above.

Accordingly, while any compatible processing method may be used to apply TiOₓ layers, solvent processing is preferred. In solvent processing, a layer of a solution or suspension such as a colloidal suspension of one or more TiOₓ precursors is applied. Solvent is removed, most commonly by evaporation to yield a continuous thin layer of TiOₓ, or a TiOₓ precursor which is converted to TiOₓ upon further processing such as mild heating. While the invention is not limited to any theories, it is believed that the precursor converts to TiOₓ by hydrolysis and condensation processes as follows:

Ti(OR)₄+4H₂O—>TiOₓ+YROH.

The TiOₓ precursor can be a titanium alkoxide such as titanium(IV) butoxide, titanium(IV) chloride, titanium(IV) ethoxide, titanium(IV) methoxide, titanium(IV) propoxide. Other titanium sources such as Ti(SO₄)₂ and so on can also be used. Such materials are commonly available and soluble in lower alkanols such as C₁-C₄ alkanols which are generally compatible with and nondestructive to other organic polymer layers commonly found in microelectronic devices. Alkoxyalkanols such as methoxy-ethanol and the like can also be used. The solvents selected should not react with the TiOₓ precursor. Therefore, care should be taken when aqueous solvents or mixed aqueous/organic solvents are used during processing as the water component can cause premature reaction such as hydrolysis of the TiOₓ precursor. Another factor to be considered in selecting a titanium source and solvent is the ability of the precursor solution to wet the substrate upon which the solution is to be spread. The lower alkanol-based solutions/suspensions described above provide good wetting with organic layers.

The titanium concentration in the solution/suspension can vary from as low as 0.01% by weight to as high as 10% by weight, or greater. In some embodiments, titanium concentration ranging from about 0.5 to 5% by weight has given good results.

The TiOₓ precursor solution/suspension can be spread using various conventional methods. In some embodiments, spin casting is used and has provided good results.

The TiOₓ layer is formed by heating the solution of starting materials for a time and at a temperature suitable to react the starting materials but not so high as to cause conversion of the starting materials to a full stoichiometric oxide. Temperatures of from about 50 degrees centigrade to about 150 degrees centigrade and times of from about 0.1 hour (at higher temperatures) to about 12 hours (at lower temperatures) can be employed. In some embodiments, the temperature can range from about 80 degrees centigrade to about 120 degrees centigrade for a time period from 1 to 4 hours, with the higher temperatures using the shorter times and the lower temperatures needing the longer times.

It is desirable to exclude oxygen during the casting and heating of the solution of TiOₓ precursors. This prevents premature conversion of the precursor to TiOₓ or conversion of the TiOₓ precursor to TiO₂ full oxide. This can be accomplished by carrying out the casting and solution preparation under-vacuum or in an inert atmosphere such as argon or nitrogen atmosphere.

This invention will be further described with reference to the following Examples. The Examples are provided to illustrate the invention and are not intended to limit the scope of the invention in any way.

### Example 1

### Solution-processed Titanium Oxides

The TiOₓ material was prepared using a novel sol-gel procedure as follows: 10 mL titanium(IV) isopropoxide (Ti[OCH(CH₃)_{2]4}, 99.999%, Sigma-Aldrich Corporation) was mixed with 50 mL 2-methoxyethanol (CH₃OCH₂CH₂OH, 99.9+%, Sigma-Aldrich) and 5 mL ethanolamine (H₂NCH₂CH₂OH, 99+%, Sigma-Aldrich) in a three-necked flask equipped with a condenser, thermometer, and an argon gas inlet/outlet respectively. The mixed solution was then heated to 80° C. for 2 hours in a silicon oil bath under magnetic stirring, followed by heating to 120° C. for 1 hour. The two-step heating (at 80° C. and 120° C.) was then repeated. A TiOₓ precursor solution was prepared in isopropyl alcohol.

Dense TiOₓ layers were prepared from the TiOₓ precursor solution. The precursor solution was spin-cast in the air on top of a semiconducting polymer layer comprising P3HT with thicknesses ranging from 20 to 40 nm. Subsequently, the films were heated at 80° C. for 10 minutes in the air. During the process the precursor converted to a solid-sate TiOₓ layer.

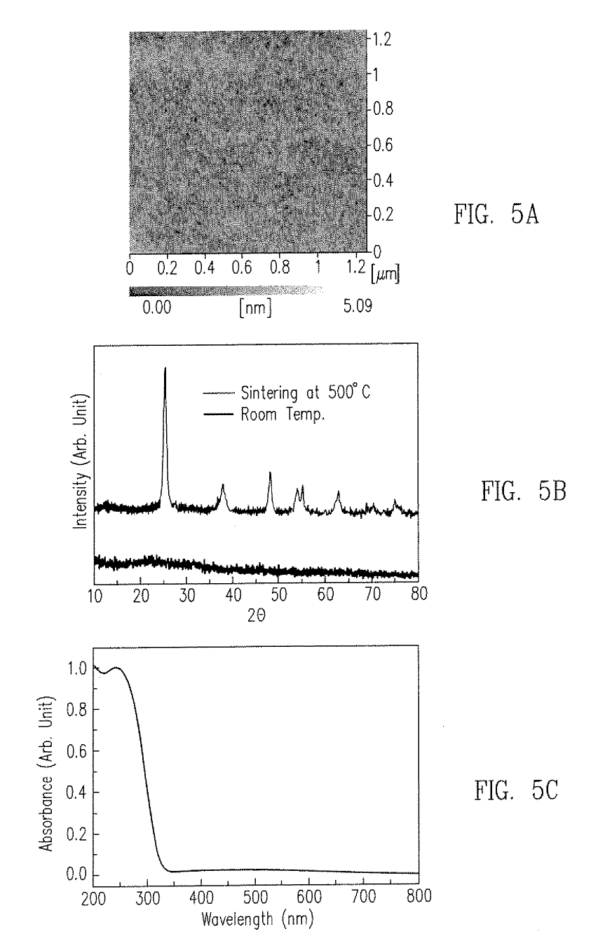

FIG. 5A is an atomic force microscope scan showing that the resulting TiOₓ films were substantially smooth and transparent with surface features smaller than a few nm. Analysis by X-ray Photoelectron Spectroscopy (XPS) revealed an oxygen deficiency at the surface of the thin film samples with Ti:O ratio of 42.1:56.4 (% ratio); hence titanium “suboxide,” or TiOₓ. was formed.

X-ray diffraction (XRD) results shown in FIG. 5B confirm that the TiOₓ film is substantially amorphous. The physical properties of the films are excellent. Time of flight measurements on these TiOₓ films indicate that the electron mobility (μₑ) is μₑ≈1.7×10⁻⁴ cm²/Vs, somewhat higher than the mobility values obtained from amorphous oxide films prepared by typical sol-gel processes. The absorption spectrum of the film exhibits a well-defined absorption edge at E_{g}≈3.7 eV as shown in FIG. 5C. Using optical absorption and Cyclic Voltammetry (CV) data, the energies of the bottom of the conduction band and the top of the valence band of the TiOₓ material were determined as −4.4 eV and −8.1 eV, respectively, referenced to the vacuum. The TiOₓ layer satisfies the electronic structure requirements of an inserting layer: the conduction band edge of TiOₓ is −4.4 eV (relative to the vacuum), which is well matched with the Fermi level of the Al cathode (−4.3 eV); the valence band edge at −8.1 eV assures that the TiOₓ functions as a hole blocking layer.

### Example 2

### TiOₓ as an Oxygen Barrier and an Oxygen Scavenging Layer

Comparison studies of photoluminescence (PL) stability of polyfluorene (PF) with and without a TiOₓ layer were carried out to confirm the oxygen barrier and scavenging properties of the TiOₓ layer. Four films with the following structures were prepared by spin-casting: glass/PF, glass/TiOₓ/PF, glass/PF/TiOₓ, and glass/TiOₓ/PF/TiOₓ. The films were then heated for 15 hours at 150° C. in the air.

It is known that the PF type materials degrade with an appearance of a long-wavelength emission around 500-600 nm after heating in the air. This green emission peak arises by energy transfer from singlet excitons on the PF chains to keto-defect sites that form by reaction with oxygen present in the luminescent polymer. Therefore, it is expected that the four different samples would exhibit different peak intensities for the long wavelength emission because of the shielding and oxygen scavenging effect of the TiOₓ layer.

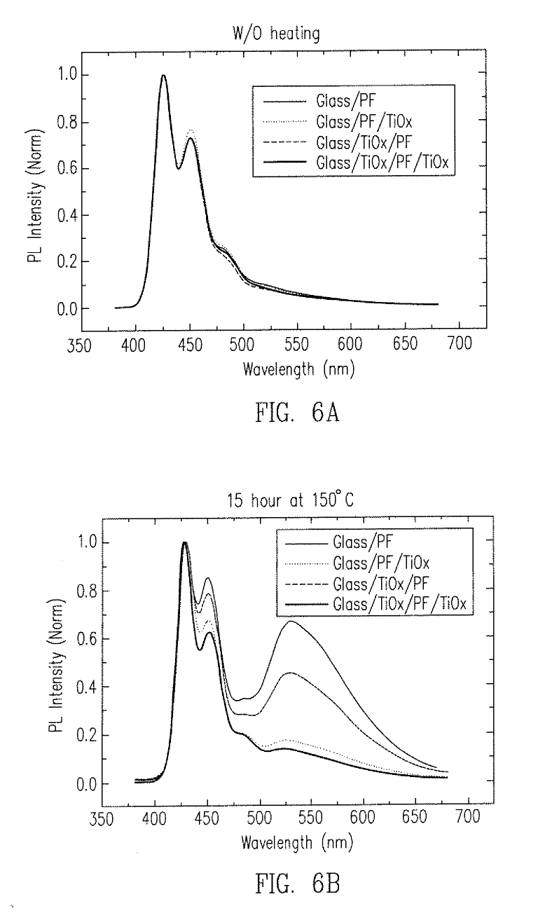

FIG. 6A shows the initial PL spectra of all the films which are typical of PF without any peak in the region of 500-600 nm. The initial PL color was pure blue.

After the films were heated for 15 hours at 150° C. in the air, the PF film without a TiOₓ layer developed a pronounced peak in the PL emission spectrum in the 500-600 nm region, as shown in FIG. 6B, and the emission color changed from blue to green. For the PF films covered by a TiOₓ layer (glass/PF/TiOₓ and glass/TiOₓ/PF/TiOₓ), the PL peak in the 500-600 nm spectral range is significantly reduced (almost completely eliminated); the emission color remains blue. Note that the TiOₓ layer provided some benefit even when it was beneath the PF (glass/TiOₓ/PF): the green emission peak is smaller than that emitted from the glass/PF film. Since the glass substrates (few mm thick) are excellent shielding materials, the introduction of a TiOₓ layer between the glass and PF would not be expected to provide any barrier to oxygen or water vapor. However, the intensity difference of the green peak between the glass/PF and glass/TiOₓ/PF samples (also a small difference between the glass/PF/TiOₓ and glass/TiOₓ/PF/TiOₓ films) shows that the TiOₓ layers have an effect of oxygen scavenging as well as oxygen shielding.

More direct evidence of the oxygen shielding and oxygen scavenging effects of the TiOₓ layers comes from X-ray photoelectron spectroscopy (XPS) measurements. This method was employed to directly compare the oxygen concentration inside the polymers with and without a TiOₓ layer. The XPS analysis was performed using VG Scientific ESCALAB 250 XPS spectrometer equipped with a monochromated Al K-alpha X-ray source (hv=1486.6 eV) at 15 kV. The analysis area was approximately 500 μm in diameter. Utilizing alkoxy-substituted 2-phenyl PPVs as a luminescent material, glass/polymer and glass/polymer/TiOₓ films were prepared and subsequently annealed for 48 hours at 150° C. in air to accelerate the oxidation of the polymer films. Then in order to compare the oxygen ratio of the two polymers, the TiOₓ layer was removed from the glass/polymer/TiOₓ sample by using the XPS depth profiling technique. The measured polymer layers of both samples were etched with a depth of around 10 nm to remove any surface oxygen.

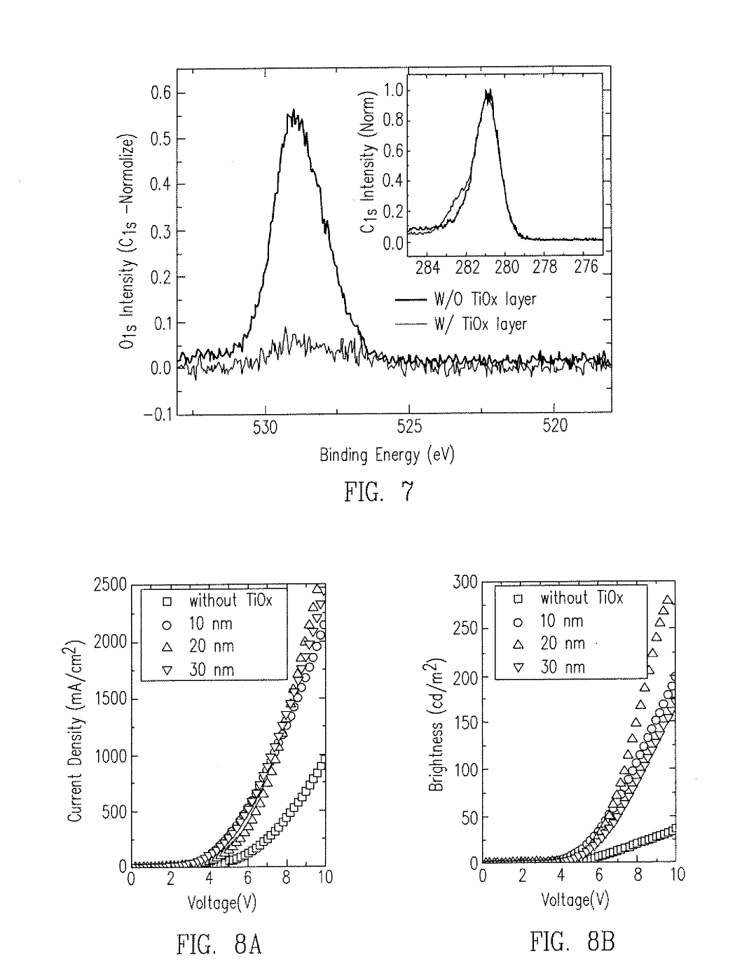

FIG. 7 shows the relative ratio of O₁ₛ/C₁ₛ inside the polymers with and without a TiOₓ layer. The polymer without a TiOₓ layer has a high intensity peak of O₁ₛ/C₁ₛ with an asymmetric feature, whereas this signal is hardly detectable in the polymer layer covered with a TiOₓ layer. These data provide direct evidence of oxygen barrier and scavenging effects of the TiOₓ layers of the invention in the polymer-based electronic devices.

### Example 3

### Polymer Diodes and Polymer Light-Emitting Diodes with Enhanced Performance as a Result of a Titanium Oxide (TiOₓ) Layer

Polymer diodes and LEDs were fabricated in the sandwich structure: ITO/PEDOT:PSS/Polymer/TiOₓ/Al. The semiconducting polymer used in this example was MEH-PPV available from Organic Vision Inc. The thickness of the MEH-PPV layer was approximately 100 nm. The TiOₓ precursor solution (1 wt %) was spin-cast (6000 rpm) onto the semiconducting polymer layer with a thickness around 20 nm, and heated at 80° C. for 10 minutes in the air. During this process the precursor converted to TiOₓ. Subsequently the devices were pumped down in vacuum (<10⁻⁶ Torr), and then Al electrode with a thickness around 150 nm was deposited. The deposited Al electrode area defined an active area of the device as 16 mm². The current density-voltage-luminance characteristics were measured using a Keithley 236 source measurement unit along with a calibrated silicon photodiode inside a glove box.

FIG. 8A-8B show the current density versus voltage (J-V) and brightness versus voltage (L-V) characteristics of the devices comprising a TiOₓ layer with various thicknesses (MEH-PPV as a semiconducting polymer) in the forward direction. For the devices without a TiOₓ layer, the turn-on voltage for current injection was about 5V. When a TiOₓ layer was inserted between the polymer and Al cathode, a significant increase in current density (j) was observed compared with the current density of a conventional device without a TiOₓ layer at the same voltage. For example, for the conventional device, the current density was j≈500 mA/cm² at 8 V, but increased to j≈1500 mA/cm² at the same voltage for the devices with a TiOₓ layer. Since the hole transport was blocked, the enhanced current density indicates that electron injection is improved. It should be noted that the J-V curves are not sensitive to the thickness of the TiOₓ layer between 10-30 nm.

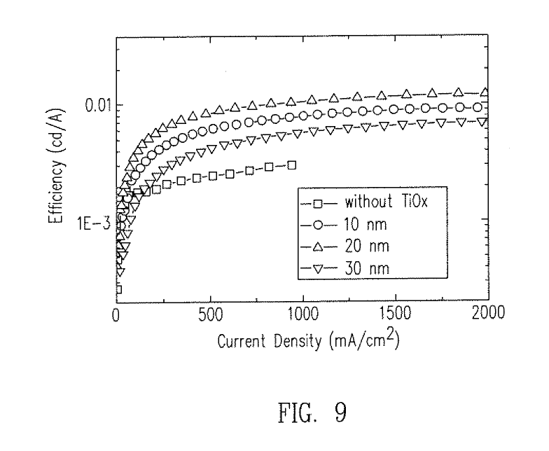

The L-V curves shown in FIG. 8B demonstrate significantly enhanced performance for devices as a result of the insertion of a TiOₓ electron transport layer (ETL). For devices with a TiOₓ layer, the brightness increased dramatically over that of the conventional device without a TiOₓ layer. The device performance was sensitive to the thickness of the TiOₓ layer. The device comprising a TiOₓ layer with a thickness of 20 nm exhibited a higher brightness than the other two devices which had a thickness of 10 nm and 30 nm respectively. As shown in FIG. 9, the luminous efficiency of the 20 nm-thickness device is almost one order of magnitude higher than that of the conventional device.

It should be pointed out that because Al was used as the cathode, the efficiency of the device was low compared to that of devices made with Ca or Ba as the cathode material. Because structures are provided to demonstrate improved lifetime of diodes and LEDs as a result of the insertion of a TiOₓ layer (see Examples below), Ca or Ba materials were not used as the device performance was monitored in the air. Nevertheless, the data in FIGS. 8 and 9 demonstrate relatively good electron transport through the TiOₓ layer and relatively good electron transport across the interface between the TiOₓ and the semiconducting polymer.

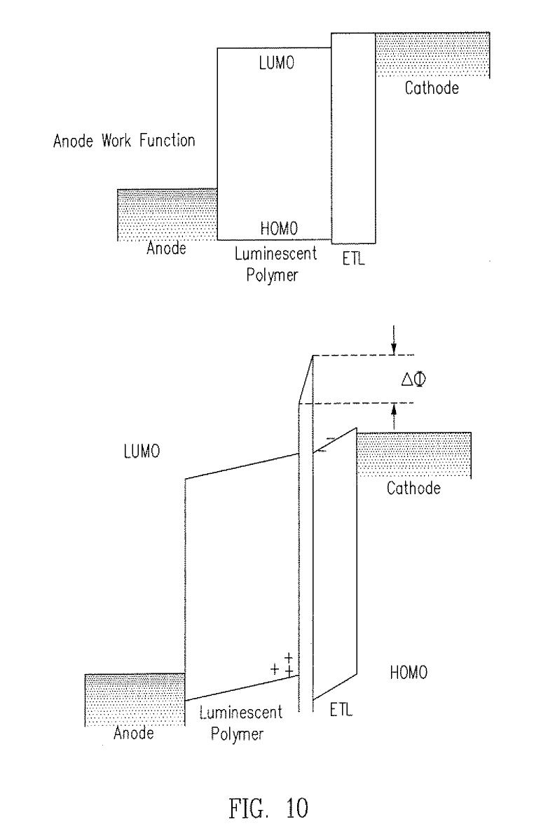

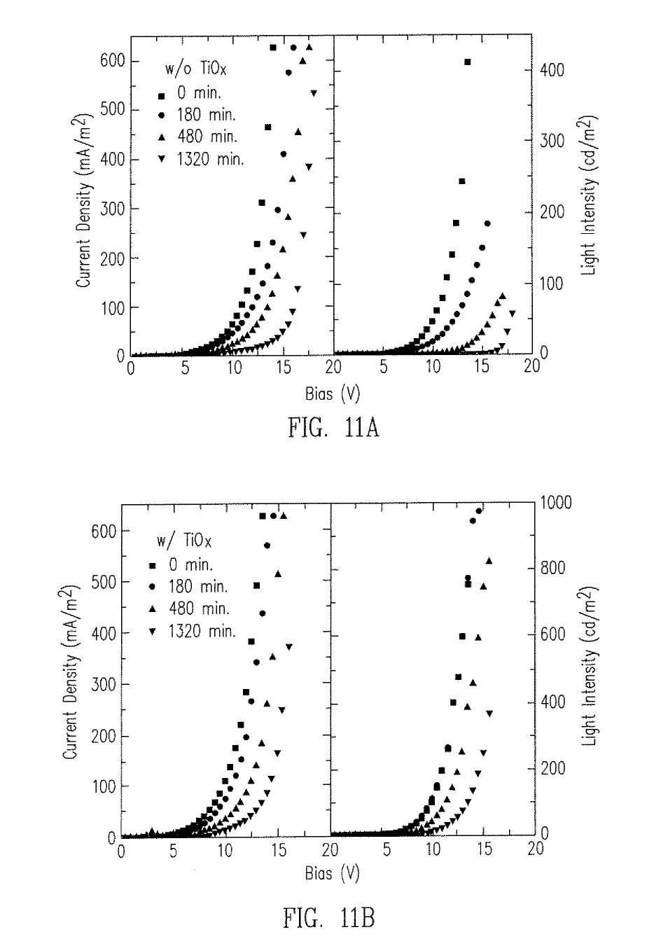

FIG. 10 shows the electronic structure of an LED with an electron transport layer (ETL). The ETL creates a barrier at the interface of two polymers that blocks the flow of holes. As shown in FIG. 10, a dipole double layer forms at the interface. If the dipole layer is sufficiently thin, electrons can tunnel through the barrier into the π*-band of the semiconducting polymer. As a result, the electron and hole currents become more balanced.

### Example 4

### Polymer Diodes and Light-Emitting Diodes with Enhanced Lifetime as a Result of a Titanium Oxide (TiOₓ) Electron Transport Layer

Polymer LEDs comprising a TiOₓ layer between an active layer and Al electrode as shown in FIG. 1 were fabricated. For comparison, conventional polymer LEDs without a TiOₓ layer were also fabricated. In these experiments, “super yellow” (SY) polymer, a soluble derivative of poly(paraphenylene vinylene, available from Covion Co. was used as the luminescent polymer. A layer of PEDOT:PSS (Bayton P VP Al 4083) available from Bayton was spin-cast onto ITO to form a bilayer anode. A solution of SY (0.7 wt.-% in toluene) was spin-cast (2000 rpm) on top of the PEDOT:PSS layer, and baked at 80° C. for 30 minutes. The thicknesses of the SY layer was about 100 nm. Then, a TiOₓ precursor solution (1 wt %) was spin-cast (6000 rpm) onto the SY emitting layer with a thickness about 20 nm, and heated at 80° C. for 10 minutes in the air. During this process the precursor converted to TiOₓ. Subsequently the devices were pumped down in vacuum (<10⁻⁶ Torr), and then Al electrodes with thickness about 150 nm were deposited. The deposited Al electrode area defined an active area of the devices as 16 mm². The current density-voltage-luminance characteristics were measured using a Keithley 236 source measurement unit along with a calibrated silicon photodiode inside a glove box.

After fabrication and initial characterization, the devices were stored in the ambient atmosphere to monitor the degradation of the devices versus storage time. No packaging or encapsulation was used except for a TiOₓ layer between the SY layer and the cathode.

FIGS. 11A and 11B show the current density versus voltage (J-V) and the luminance versus voltage (L-V) characteristics of the devices measured after various storage periods in the air. The devices without a TiOₓ layer initially exhibited characteristics typical of polymer LEDs made with SY and Al cathode, with an onset voltage of ˜8 V and luminance of L≈400 cd/m² at 13 V (FIG. 11A). After storage in the air, however, the device performance rapidly degraded. After three hours (180 minutes), the luminance dropped below 100 cd/m² at 13 V, corresponding to one fourth of the initial value, and became almost negligible after 8 hours (480 minutes). The onset voltage also increased considerably as the storage time increased.

In contrast, the devices with a TiOₓ layer showed amore robust behavior as illustrated in FIG. 11B. The luminescence of the devices remained almost unchanged after three hours in the air with L≈700 cd/m² at 13 V, and slightly decreased to ˜600 cd/m² at 13 V after 8 hours (480 minutes). After 22 hours (1320 minutes) the device retained a brightness of ˜400 cd/m² at 15 V. Remarkably, without any additional packaging, a thin TiOₓ layer (e.g., ˜30 nm) slowed the degradation by approximately two orders of magnitude.

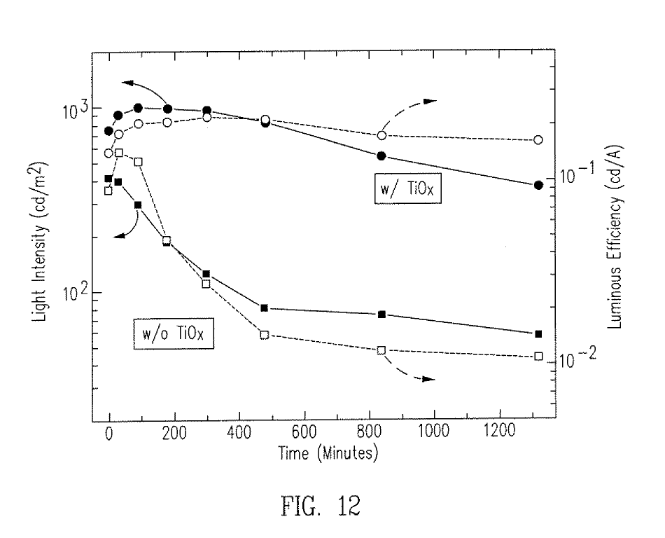

In addition to the enhanced lifetime, the performance of the TiOₓ devices was also improved compared with that of conventional devices. As shown in FIG. 12, the brightness and efficiency actually increased initially. For example, the brightness at 13V increased from approximately 700 cd/m² to about 1000 cd/m² during the first two hours, whereas the initial value of the conventional devices was only L≈400 cd/m² at 13V and decayed rapidly to almost negligible values within few hours. Therefore, a TiOₓ layer provides an attractive approach to reducing the sensitivity of polymer LEDs to oxygen and water vapor.

Because of the reduced sensitivity, simple barrier materials might be sufficient to provide long lifetime to diodes, diodes arrays, polymer LEDs and arrays of polymer LEDs in display and lighting applications.

### Example 5

### Polymer Solar Cells with Enhanced Lifetime as a Result of a Titanium Oxide (TiOₓ) Optical Spacer Layer

Polymer solar cells comprising a TiOₓ layer as shown in FIG. 2 were fabricated using poly(3-hexylthiophene) (P3HT) as the electron donor and [6,6]-phenyl-C₆₁ -butyric acid methyl ester (PCBM) as the electron acceptor. The ITO-coated glass substrates were cleaned in an ultrasonic bath with a detergent, distilled water, acetone, and isopropyl alcohol and then dried overnight in an oven at about 100° C. Highly conducting PEDOT:PSS was spin-cast (5000 rpm) with a thickness about 40 nm from aqueous solution after treatment with UV-ozone for 40 minutes. The substrates were dried at 140° C. for 10 minutes in the air, and then transferred to a nitrogen filled glove box for spin-casting the P3HT:PCBM layer. The chloroform solution comprised of P3HT (1 wt. %) or P3HT (0.8 wt. %) was then spin-cast at 1200 rpm on top of the PEDOT:PSS layer. The thickness of the active layer was about 200 nm. Then, a TiOₓ layer (about 30 nm) was spin-cast (4000 rpm) on top of the P3HT:PCBM composite from the precursor solution (1 wt. %), and heated at 80° C. for 10 minutes in the air. Thermal annealing was carried out by directly putting the samples on the hot plate at 150° C. for 10 minutes in a nitrogen filled glove box. Subsequently the device was pumped down in vacuum (<10⁻⁶ Torr), and an Al electrode with a thickness of about 150 nm was deposited. The area of the Al electrode defined the active area of the device as 4.5 mm². Thermal annealing was carried out by directly placing the completed devices without a TiOₓ layer on a hot plate at 150° C. in a glove box filled with nitrogen gas. After annealing, the devices were put on a metal plate and cooled to room temperature before the measurements were carried out.

For calibration of solar simulators, the mismatch of the spectrum (the simulating spectrum) obtained from the Xenon lamp (150 W Oriel) and the solar spectrum using an AM 1.5 filter was carefully minimized. The light intensity was calibrated using a standard silicon photovoltaic (PV) solar cell from the National Renewable Energy Laboratory (NREL). Measurements were carried out with the solar cells inside a glove box by using a high quality optical fiber to guide the light from the solar simulator (outside the glove box). Current density-voltage curves were measured with a Keithley 236 source measurement unit.

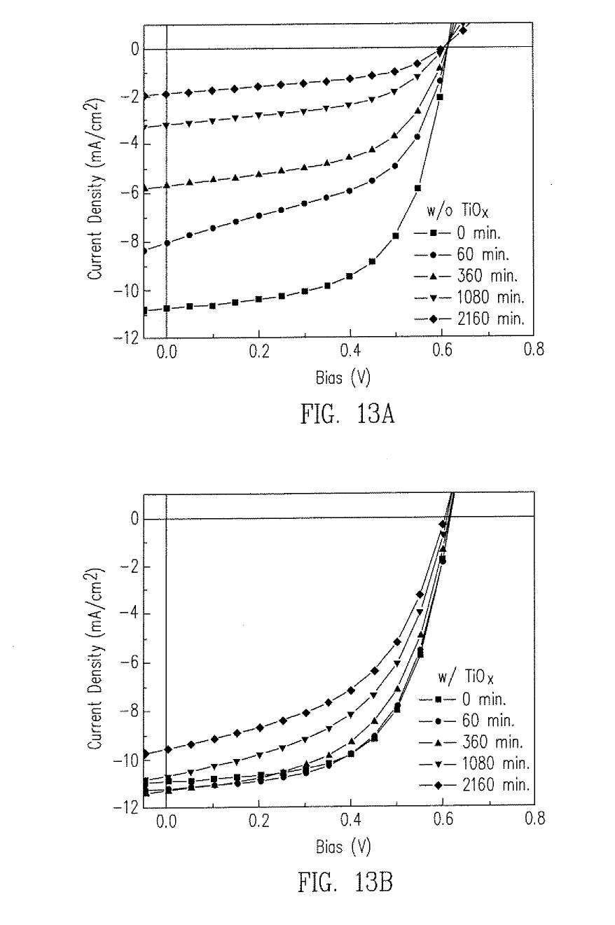

The TiOₓ layer improved the lifetime of polymer-based solar cells. FIGS. 13A-13B show the current density vs. voltage (J-V) characteristics of a photovoltaic cell with and without a TiOₓ layer under AM 1.5 illumination at irradiation intensity of 100 mW/cm². The conventional device without a TiOₓ layer showed a typical photovoltaic response with device performance comparable to that reported in previous studies; the short circuit current (I_{sc}) was I_{sc}=10.7 mA/cm², the open circuit voltage (V_{oc}) was V_{oc}=0.62, and the fill factor (FF) was FF=0.60. These values correspond to a power conversion efficiency (ηₑ=I_{sc}V_{oc}FF/P_{inc}, where P_{inc} is the intensity of incident light) of ηₑ=4.0%.

When these conventional devices were stored in the ambient air, a dramatic decrease in I_{sc} was observed as the storage time increased, I_{sc} dropped to <15% of the initial value after 36 hours (2160 minutes). Note, however, that the V_{oc} remained almost constant at 0.62 V, indicating that the devices still function properly without catastrophic failure. For the device with a TiOₓ layer, the initial performance was comparable to those of the conventional devices without a TiOₓ layer; I_{sc}=10.8 mA/cm², V_{oc}=0.62 V, FF=0.61, yielding ηₑ=4.1%. Note, however, that the conventional devices were fabricated by using postproduction heat-treatment at 150° C. to improve the efficiency, whereas the devices with a TiOₓ layer were prepared by preheat-treatment. As a result, the initial performance of the two devices were almost identical. However, the devices with a TiOₓ layer exhibited quite different behavior with increased storage time. The devices with a TiOₓ layer showed a much longer lifetime; even after 36 hours storage in the air, I_{sc} remained at almost 90% of its initial value.

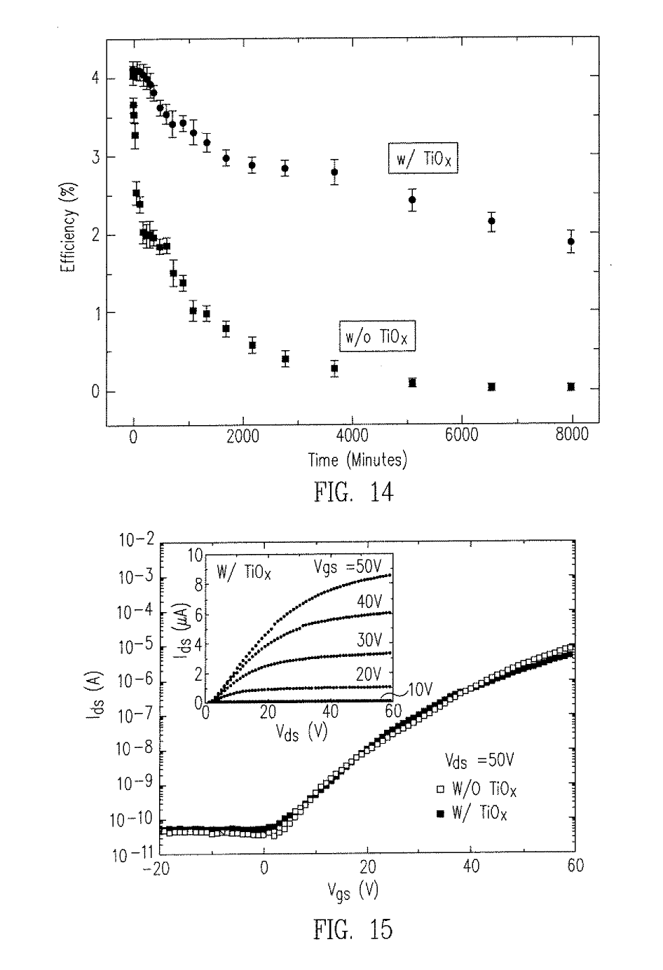

The lifetime enhancement of the devices including a TiOₓ layer is evident in FIG. 14. The efficiency of the conventional devices decreased abruptly to half of the initial value within first 200 minutes, and then continued to drop below ηₑ=1% after storage in the air for 1000 minutes. The devices with a TiOₓ layers retained at 3% efficiency after 2000 minutes; even after 8000 minutes, ηₑ=2% (half the initial value). The reduced fill-factor dominated the degradation of the devices with a TiOₓ layer, thus the degradation appeared to be mostly a result of an increase in series resistance. Thus, the data clearly demonstrate that a TiOₓ layer enhanced the lifetime of polymer photovoltaic cells. Compared with the conventional devices without a TiOₓ layer, the unpackaged lifetime was enhanced by a factor of 40. By also functioning as an optical spacer, a TiOₓ layer offers the potential for increasing the efficiency as well as the device lifetime. Because of the reduced sensitivity to oxygen and water vapor, simple barrier materials might be sufficient to provide sufficiently long lifetime for commercial implementation.

### Example 6

### Polymer Field-Effect Transistors with Enhanced Lifetime as a Result of a Titanium Oxide (TiOₓ) Capping Layer

Polymer FETs were fabricated in a bottom contact geometry as shown in FIG. 3. The FET structures were fabricated on a heavily doped n-type Si wafer (which functioned as the gate electrode) with a 200 nm thick thermally grown SiO₂ layer (gate dielectric). The channel length (L) and the channel width (W) of the devices were 5 pm and 1000 μm, respectively. Aluminum source and drain electrodes (50 nm) were deposited on a SiO₂ insulating layer by e-beam evaporation. PCBM (or P3HT) were used as the active semiconductor layer in the channel. Before depositing P3HT (or PCBM) active layer, aluminum electrodes were etched with standard aluminum etchant to remove aluminum oxide layer. After depositing the PCBM (or P3HT) by spin-casting, a TiOₓ layer with a thickness about 30 nm was spin-cast on top of the FET device. The TiOₓ solution was spin-cast at 5000 rpm for 60 seconds on top of the semiconducting polymer layer. In this example, the TiOₓ layer serves to reduce the sensitivity of the FET to oxygen and water vapor.

Electrical characterization of the device was performed using a Keithley semiconductor parametric analyzer (Keithley 4200) under N₂ atmosphere. In order to investigate the environmental stability of the FET devices, the devices were taken out of the glove box and left in the air. The device performance was periodically monitored as a function of time.

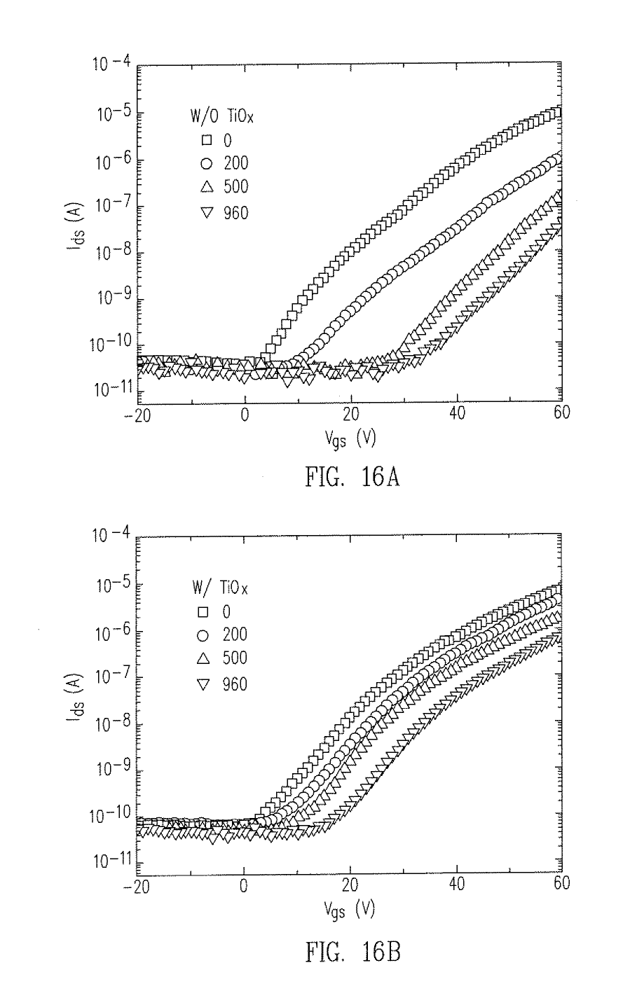

A TiOₓ layer enhanced the lifetime of polymer field-effect transistors (FETs). FIG. 15 compares the transfer characteristics of PCBM-FETs with and without a TiOₓ layer, measured just after fabrication without any exposure to the air. The drain-source current (I_{ds}) curves versus applied gate voltage (V_{gs}) were typical of n-channel organic FETs; the device performance was comparable to that conventional devices. Moreover, the presence of a TiOₓ layer on top of the active layer did not influence the device performance when measured in vacuum without exposure to the air. After exposure to the air, however, the two devices exhibited quite different behavior as shown in FIGS. 16A-16B. For the devices without a TiOₓ layer, I_{ds} decreased rapidly and the turn-on voltage (Vₜₒ) shifted to higher values with increased exposure time, whereas the devices with a TiOₓ capping layer showed a slow decrease in I_{ds} and small shift of Vₜₒ. It is well known that both the shift of Vₜₒ to higher values and the decrease in I_{ds} originate from the diffusion of oxygen and water vapor into PCBM polymer. The data in FIGS. 16A and 16B demonstrate that a TiOₓ layer reduced the diffusion of oxygen and water vapor into polymer-based FETs.

The effect of a TiOₓ capping layer is more pronounced in the study of the electron mobility (μ). The mobilities were extracted form the slope of (|I_{ds}|)^{1/2} vs. V_{gs} (not presented here) in the saturation region using following equation:

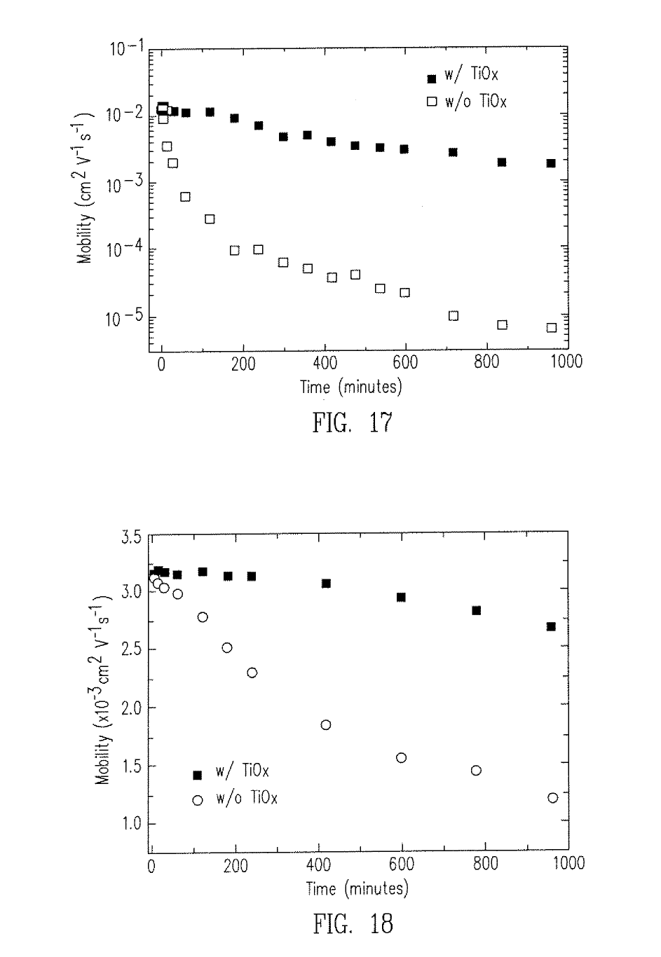

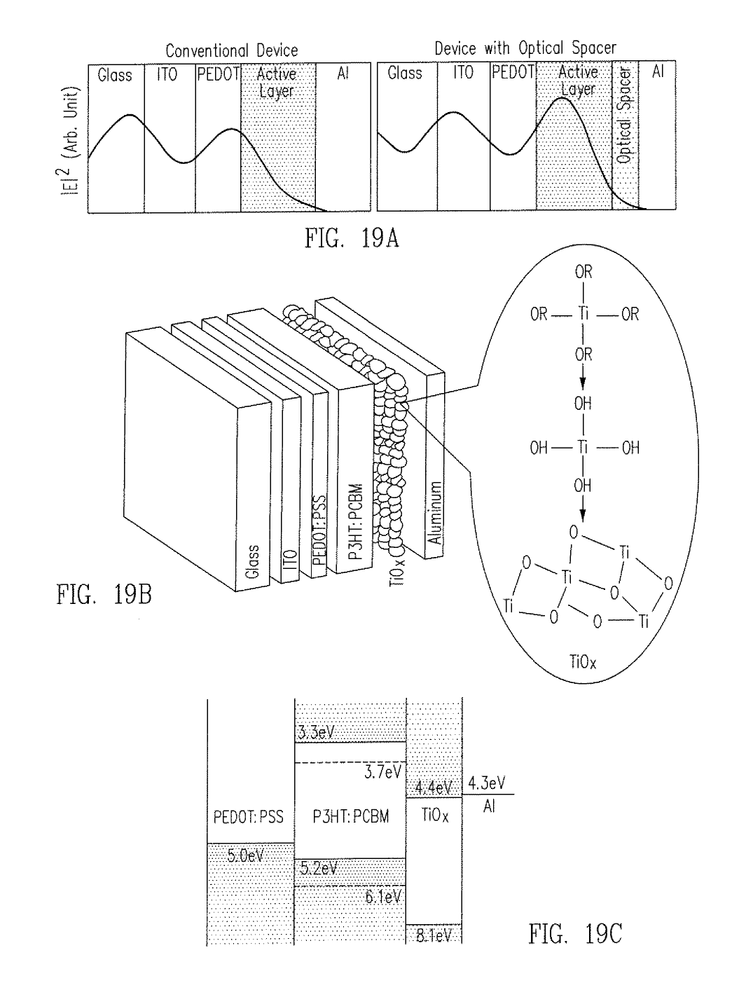

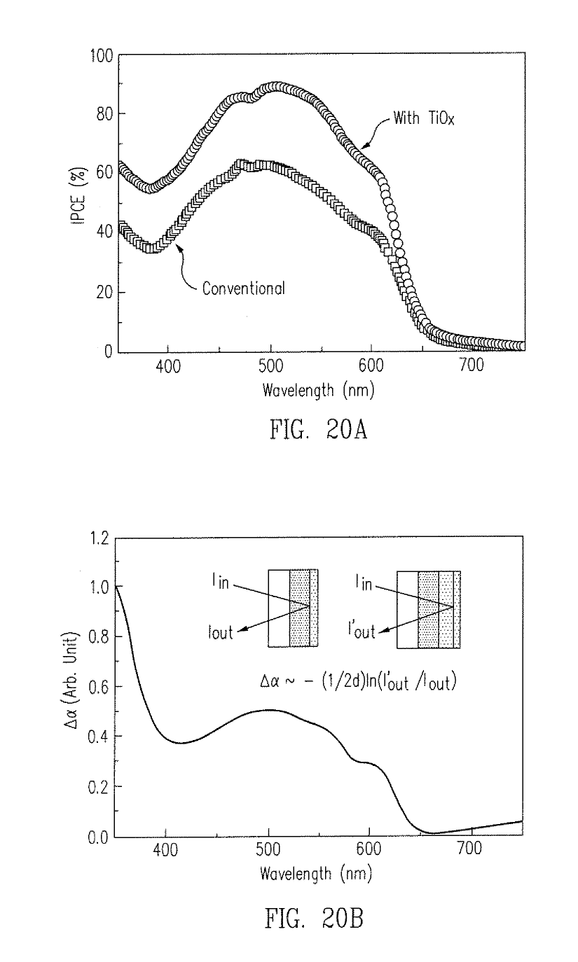

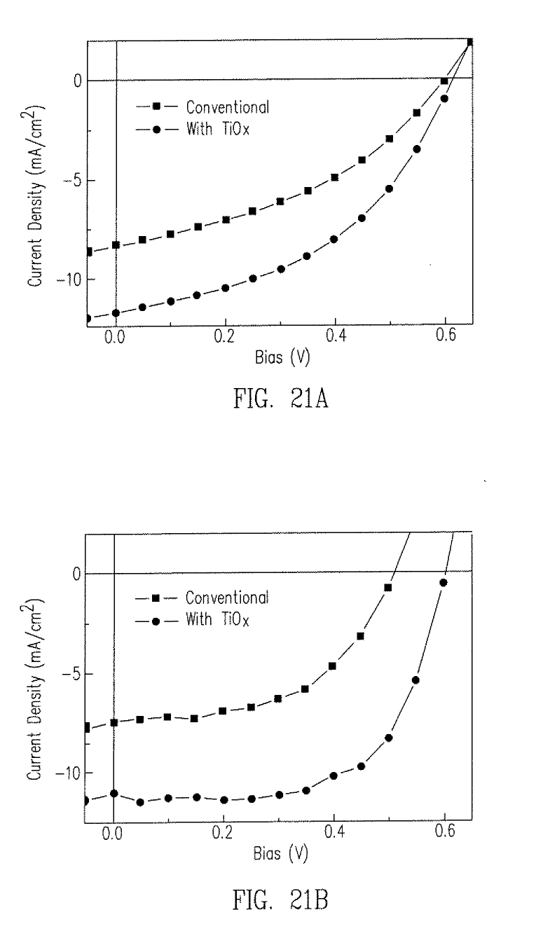

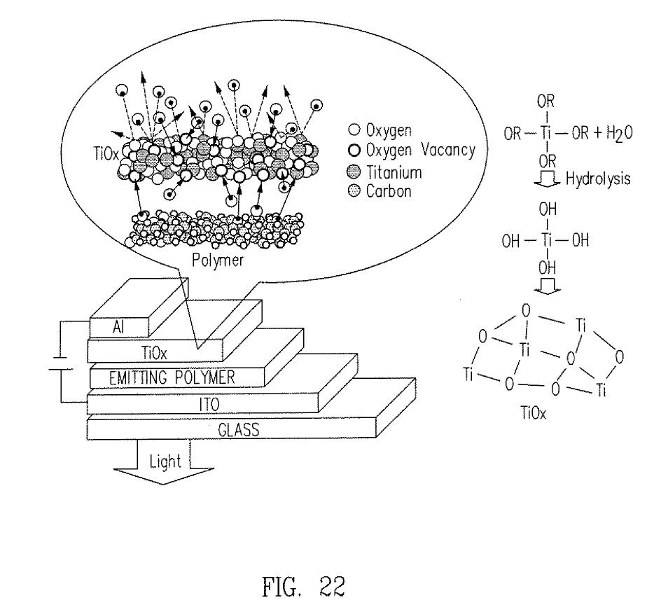

I_{ds}=(WCᵢ/2L)μ(V_{gs}-V_{T})²

where V_{T} is the threshold voltage, and Cᵢ is the capacitance per unit area of insulating layer (for 200 nm layer of SiO₂, Cᵢ=17 nF/cm²). FIG. 17 shows the results obtained for p as a function of exposure time. While the mobility of the devices without a TiOₓ layer decreased rapidly (almost two orders of magnitude decrease within first 100 minutes), the devices with a TiOₓ capping layer were much more stable during exposure to the air with less than one order of magnitude decrease even after 1000 minutes of air exposure.

The lifetime enhancement provided by a TiOₓ is not limited to PCBM as the semiconducting layer in the channel, but appears to be general. For example, FETs using P3HT polymer capped with a TiOₓ layer also exhibited enhanced device lifetimes as shown in FIG. 18. Therefore, as a result of a TiOₓ capping layer and the associated reduced sensitivity to oxygen and water vapor, simple barrier materials might be sufficient to enable the lifetime required for printed, flexible, plastic electronics.

The use of a TiOₓ capping layer can also be used to extend the lifetime of other plastic electronic devices such as diodes, photodetectors and more generally plastic electronic circuits. When employed as a capping layer for diodes, photodetectors or plastic electronic circuits, the TiOₓ capping layer does not play an active role in the device operation but serves to enhance the device lifetime.

An innovative approach to enhancing the performance and lifetime of electronic devices is described herein. A solution-based sol-gel process is provided to fabricate a titanium oxide (TiOₓ) layer on top of the active polymer layer(s) in thin-film devices. By introducing a solution-based titanium (TiOₓ) layer between an active layer and a metal such as aluminum cathode as an electron transport layer (ETL) in polymer diodes and polymer light-emitting diodes (PLEDs), both the device performance and lifetime are enhanced. Field-effect transistors (FETs), photodiodes and photodetectors fabricated from semiconducting polymers exhibit a similar lifetime extension with the addition of a TiOₓ layer on top of the semiconducting polymer. The success of this approach originates from the excellent physical properties of the new TiOₓ material, the specific process that enables low-temperature deposition of TiOₓ on top of the semiconducting polymer layer, and the oxygen/water protection and scavenging effects of TiOₓ. The addition of a TiOₓ on top of the semiconducting polymer layer improves the lifetime of unpackaged devices by nearly two orders of magnitude and thereby significantly reduces the barrier requirements of packaging materials for plastic electronics.

1. An electronic device comprising a first electrode, a second electrode, an active polymer layer between the first and the second electrodes, and a passivating layer adapted to enhance lifetime of the electronic device, wherein the passivating layer comprises a substantially amorphous titanium oxide having the formula of TiOₓ where x represents a number from 1 to 1.96.

2. The electronic device of claim 1 wherein in the formula of TiOₓ represents a number from 1.1 to 1.9.

3. The electronic device of claim 1 wherein in the formula of TiOₓ represents a number from 1.2 to 1.9.

4. The electronic device of claim 1 wherein the titanium oxide layer has a thickness ranging from 5 to 500 nanometers.

5. The electronic device of claim 1 wherein the titanium oxide layer has a thickness ranging from 5 to 100 nanometers.

6. The electronic device of claim 1 wherein the titanium oxide layer has a thickness ranging from 10 to 40 nanometers.

7. The electronic device of claim 1 wherein the titanium oxide layer is positioned adjacent to the active polymer layer.

8. The electronic device of claim 1 wherein the titanium oxide layer is positioned between the active polymer layer and one of the first and the second electrodes.

9. The electronic device of claim 1 wherein the titanium oxide layer is a boundary layer of the electronic device.

10. The electronic device of claim 1 which is a polymer diode.

11. The electronic device of claim 1 which is a polymer light-emitting diode.

12. The electronic device of claim 1 which is a photodiode.

13. The electronic device of claim 1 which is a photodetector.

14. A light-emitting diode comprising an electron-injecting electrode, a hole-injecting electrode, a luminescent polymer layer between the electron-injecting electrode and the hole-injecting electrode, and a layer of substantially amorphous titanium oxide having the formula of TiOₓ where x represents a number from 1 to 1.96.

15-17. (canceled)

18. The light-emitting diode of claim 14 wherein the layer of titanium oxide has a thickness of about 20 nanometers.

19. The light-emitting diode of claim 14 wherein the layer of titanium oxide is positioned between the luminescent polymer layer and the electron injecting electrode.

20. The light-emitting diode of claim 19 wherein the electron-injecting electrode comprises a metal electrode, the hole-injecting electrode comprises an indium-tin oxide and a hole injection layer of poly(3,4-ethylenedioxylenethiophene)-polystyrene sulfonic acid (ITO/PEDOT:PSS) bilayer electrode, the luminescent polymer layer comprises a luminescent semiconducting polymer of poly(2-methoxy, 5-(2′-ethyl-hexyloxy)-1,4-phenylenevinylene) (MEH-PPV), and the layer of titanium oxide has a thickness of about 20 nanometers.

21. A field-effect transistor comprising a gate electrode, a gate dielectric, a source electrode, a drain electrode, a semiconducting polymer layer, and a layer of substantially amorphous titanium oxide having the formula of TiOₓ where x represents a number from 1 to 1.96.

22. The field-effect transistor of claim 21 wherein the titanium oxide layer is atop the semiconducting polymer layer.

23. The field-effect transistor of claim 21 wherein the titanium oxide layer is a boundary layer of the field-effect transistor.

24-40. (canceled)
